(19) United States
(12) Patent Application Publication
(10) Pub. No.: US 2014/0014157 A1
(43) Pub. Date: Jan. 16, 2014

(54) SOLAR TRACKING SYSTEM USING CROSS-DIVIDER SHADE BOARD AND SENSOR SOLAR PANELS

(71) Applicants: Tsung Chieh LEE, Kaohsiung City (TW); Ming Hung Sun, Kaohsiung City (TW)

(72) Inventors: Tsung Chieh LEE, Kaohsiung City (TW); Ming Hung Sun, Kaohsiung City (TW)

(21) Appl. No.: 13/549,487

(22) Filed: Jul. 15, 2012

(51) Int. Cl. H01L 31/052

(52) U.S. Cl. 136/246

(57) ABSTRACT

A solar tracking assembly that incorporates a cross-divider shade board, four sensor solar panels, and a control system to automatically track sunlight. The design of this solar tracking system is very simple and economical, and it can achieve high efficiency in the power generation. The design is simple and economical because the tracking mechanism is by utilizing the same solar panels for sensing sunlight as well as for power generation. Together with a cross-divider shade board, signal wires, and a control system, the four sensor solar panels and additional standard solar panels can be assembled to facilitate automatic sun tracking. No additional electronic devices for sensing are needed other than using the standard solar panels.

The current application claims a foreign priority to the application of Taiwan No. 100125558 filed on Jul. 20, 2011.

### BACKGROUND OF THE INVENTION

1. Field of the Invention

The present invention is an enhanced solar panel assembly, a system, which can automatically track the sunlight to increase the solar energy output through the use of a cross-divider, four sensor solar panels, and a control system.

In the present solar tracking assembly, since the same solar panels for power generation are also used to sense the sunlight variation, the design of the present system is very simple and economical. In addition, since the output of electronic signals and voltage from the sensor panels are generated directly, it greatly reduces signal conversion errors. The software control design strategy for the solar tracking assembly therefore becomes straightforward.

Four sensor solar panels, together with other standard solar panels, are assembled as part of the solar panel assembly (FIG. 1.) A cross-divider shade board is integrally mounted between the four sensor solar panels. When placed under the sun the cross-divider is used to bring variation of shade to the sensor solar panels to generate differential signals for turning and rotating the solar panel assembly to track the sun. Such sensing function design by the intensity of shade for solar tracking is accurate and effective. The configuration of the present solar tracking system is very simple that it can be installed easily and quickly.

2. Description of the Related Art

The conventional solar tracking system can be classified into two types:
a) The active type (electric power required)—this type of system requires an extra sensing device, or element, to be added and mounted on or aside the system. The material of such sensing element is often fragile, unreliable, and likely to age and get damaged. It also needs a relatively complicated control program.
b) The passive type (electric power not required)—Both the left and right sides of such system are usually exposed to the sunlight so as to heat up the device. Different pressures are released due to different reception of sunlight in order to drive a mechanical structure to adjust the system to face the sun. Such type of solar tracking system often cannot automatically restore to its original, safe, position at night or during severe weather conditions. Therefore, such type of solar tracking system can hardly be directed precisely toward the sun. Besides, such type of solar tracking system cannot be remotely monitored or controlled.

### SUMMARY OF THE INVENTION

It is therefore the primary objectives of the present invention to provide a solar tracking system capable of automatically sensing the sunlight using the sensor solar panels within the solar panel assembly. This solar tracking system has the advantage of a very precise solar tracking effect as the active type of solar tracking system. The four power generation solar panels in the center of the solar panel assembly are also used as the light source sensing elements. Therefore, the overall total power generation amount from the sensor panels will not be reduced due to sensing. It is also unnecessary to mount any additional sensing device or material on or beside the solar panel. Therefore, the cost for the extra sensing element can be saved. The life span of the sensor panels can be equal, or similar to that of the other solar panels of the assembly. Therefore, the solar tracking system can be durable and economical.

To achieve the above objectives the solar tracking system of the present invention incorporates four sensing elements, which are the four specific sensor solar panels. Four sockets for the cross-divider shade board are respectively formed on the solar panel assembly at the junctions between the four sensor solar panels. The system further includes a cross-divider shade board, which is a made from opaque board materials. The cross-divider shade board is secured between the sensor solar panels through the insertion of board into the sockets. A set of signal wires extends from the backsides of the four sensor solar panels as the source of sensor signals. The cross-divider shade board can shade the sensing elements in eastern-western direction or southern-northern direction to make double-axis solid sensing identification. The sensor panels' backside signal wires are connected to the control system for reading sensor signals. When under the sun the cross-divider shade board is able to bring variation of shades to the four sensor solar panels so as to generate different voltage signals. The electronic circuit and the control system can compare the voltage signals and make judgment to control the rotation of motor so as to achieve a precise solar tracking effect.

Since the four sensor panels can generate different voltages according to different light intensities with the voltage changes as signals, such a system design is simple, stable, and more advantageous over the internal resistance change from the conventional photosensitive resistor.

The assembly of the present invention is through putting together one set of four sensor solar panels with multiple standard solar panels. Before the four sensor solar panels are assembled, the signal wires are preinstalled behind the sensor panels, which can be integrated with many other standard solar panels to form the integral solar panel assembly. The sensor signals can be generated thoroughly without affecting the power generation function as a whole. In addition, multiple standard solar panels can be connected and use only one set of four sensor solar panels as the sensing elements to collectively form the power generation framework to track the sun and generate power.

The present invention can be best understood through the following descriptions and accompanied drawings, wherein:

### BRIEF DESCRIPTIONS OF THE DRAWINGS

FIG. 1 is a front perspective view of the solar tracking system of the present invention;

FIG. 2 is a rear perspective view of the solar tracking system of the present invention;

FIG. 3 is a schematic diagram of the solar tracking system of the present invention; and

FIG. 4 is a perspective view showing the connection between the cross-divider shade board and the solar panel assembly of the solar tracking system of the present invention.

### DETAILED DESCRIPTIONS OF THE PREFERRED EMBODIMENT

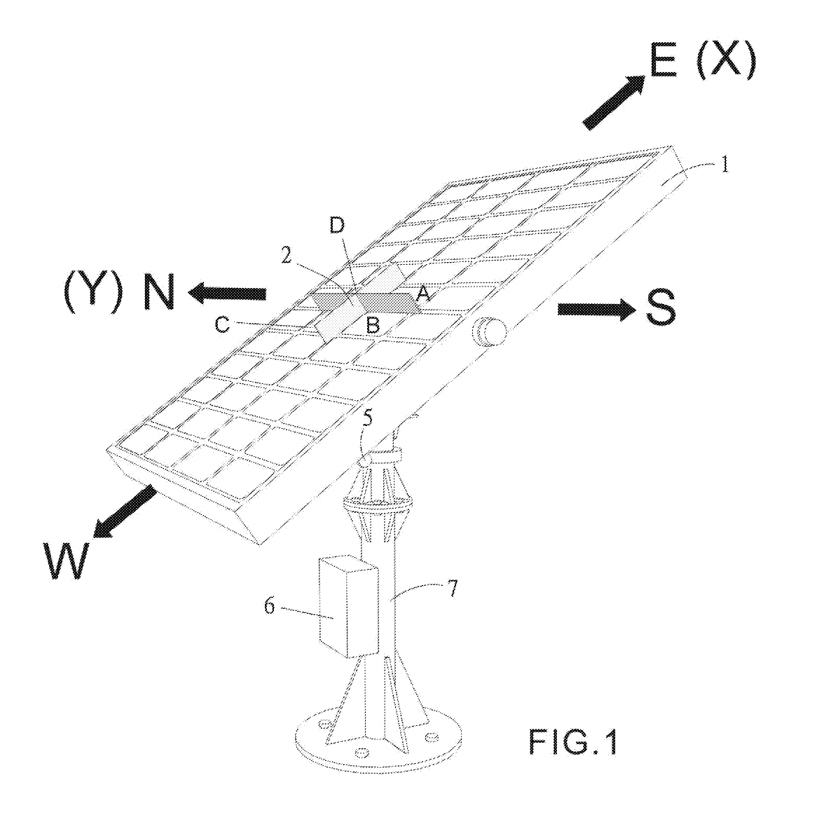

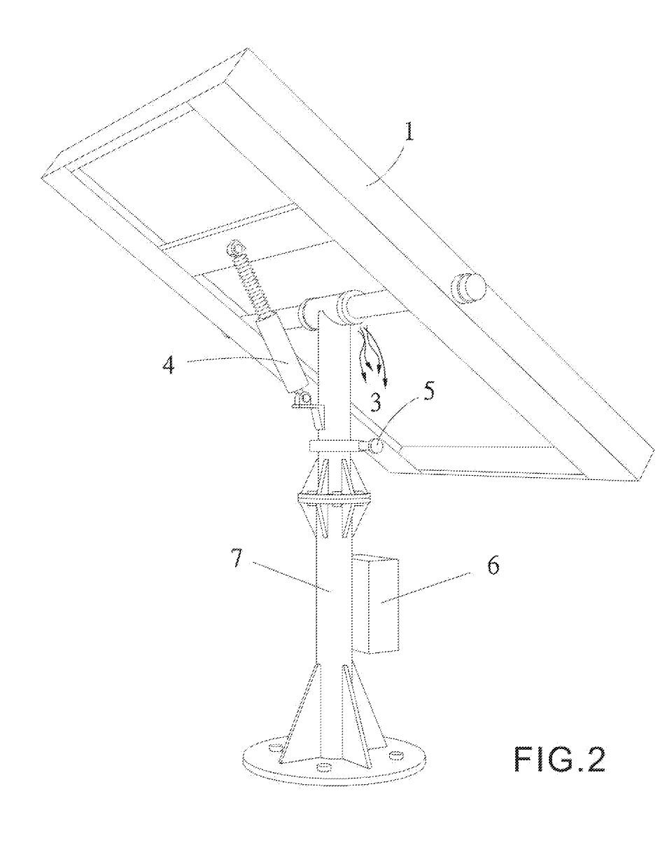

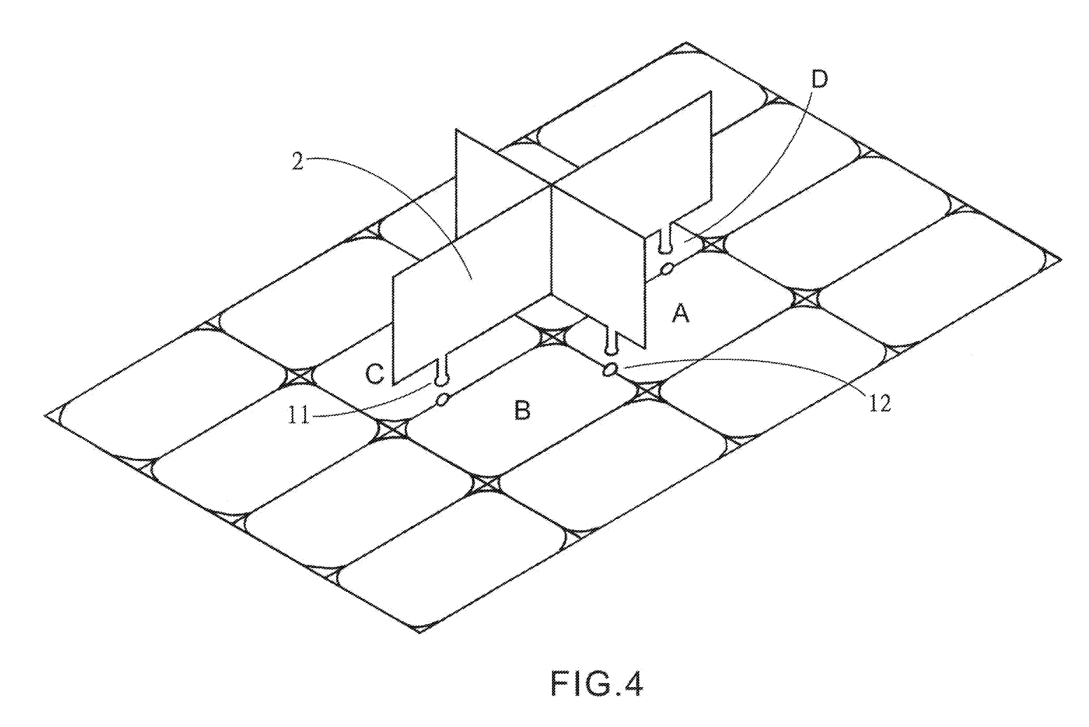

Please refer to FIG. 1 and FIG. 2. The solar tracking system of the present invention includes a solar panel assembly module 1, a cross-divider shade board 2, a movable support 7, a control system 6 mounted on the movable support 7, an electric push rod 4 connected between the solar panel assembly module l and the movable support 7 and a motor rotary seat 5. The solar panel assembly module 1 is mounted on the rotatable, movable support 7. Four specific power generating sensor solar panels A, B, C, D are installed on the upper face of the solar panel assembly module 1 as sensing elements. The panel is defined with a virtual X axis and a virtual Y axis (as shown in FIG. 1). The X axis and Y axis represent eastern & western and southern & northern directions respectively. The cross-divider shade board 2 is removable and is mounted right at the center of the panel assembly module. The bottom end of the cross-divider shade board 2 is shaped like small insertion pins 11. The junctions between the sensor solar panels A, B, C, D are formed with small circular sockets 12. The insertion pins 11 are perpendicularly inserted in the circular sockets 12 to secure the cross-divider shade board 2 between the sensor panels, as shown in FIG. 4.

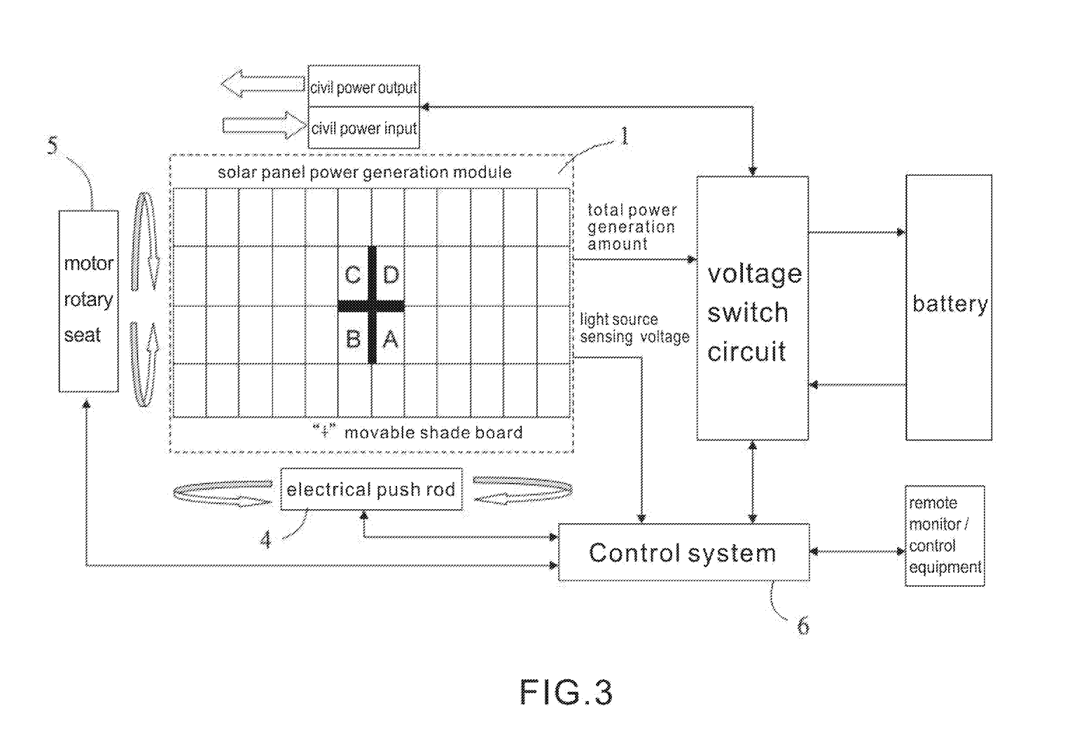

In practical operation of the present system, the sun serves as the light source. See FIG. 1, at first, the light source rises in the east to start projecting sunlight upon the solar panel assembly module 1. At this time, the set of sensor panel A and D are exposed more to the sunlight to generate stronger (than panel B and C) voltage signal, as shown in FIGS. 1 and 3, while the set of sensor panel B and C are shaded by the cross-divider shade board 2 to generate weaker (than panel A and D) or almost no voltage signals. Through the wires 3 connecting the backsides of the sensor panels to the control system 6, the signal difference is sent to the control system 6. The program of the control system 6 compares the signals and makes judgments to command the X-axis electrical push rod 4 to operate and adjust. As a result, the solar panel assembly module 1 is rotated to face the eastern light source until when the signal intensity generated by the set of sensor panel A, D are equal to that of the sensor panel B and C; that is, when the solar panel assembly module 1 faces directly toward the light source, then the electric push rod 4 stops operating.

By the same token, when the light source is placed from the west, the set of sensor panel B and C are exposed more (than sensor panel A and D) to the sunlight to generate stronger voltage signals, as shown in FIGS. 1 and 3, while the set of sensor panel A and D are shaded by the cross-divider shade board to generate weaker voltage signals (than panel B and C). The program of the control system 6 then compares and judges the signal differential to command the electrical push rod 4 to rotate the support in reverse direction until the solar panel assembly module 1 facing directly at the western light source again. The rotation stops when the voltage signals of the two sets of panels, A&D vs. B&C, are equal to, or balanced with each other.

As shown in FIG. 1 through FIG. 4, in the case that the light source emerges from the south, the set of sensor panel A and B will generate stronger voltage signals, while the set of sensor panes C and D are shaded by the cross-divider board 2 to generate weaker or almost no voltage signals. Through the wires 3 connecting the backsides of the sensor panels to the control system 6, the signal difference is sent to the control system 6. The program of the control system 6 compares and judges the signal differential to command the Y-axis motor rotary seat 5 to adjust and rotate the solar panel module 1 to the south until the solar panel assembly module 1 facing directly at the light source. The rotation is stopped when the voltage signals from the two sets of sensor panels are equal to, or balanced with each other.

The solar tracking system of the present invention is able to automatically track the light source in the combination of X axis and Y axis to achieve a universal solar tracking effect. While serving as regular power generating unit the specific four sensor panels A, B, C, D of the solar panel assembly can sense and differentiate the position of the light source so that there is no further needs to add extra sensing device—thus the cost is minimized. The durability of the panel material of both sensor solar panels and other standard solar panels are the same with each other. Moreover, the voltage signal can be directly transmitted and verified, and thus reduce the errors of signal conversion. As a result, the design of the circuit and the program is greatly simplified and the accuracy is achieved.

The above embodiment is only used to illustrate the present invention, not intended to limit the scope thereof. Some modifications to the above embodiment can be made without departing from the principle of the present invention.

What is claimed is:

1. A solar tracking system capable of automatically tracking sunlight through utilizing a cross-divider shape board and sensor solar panels, comprising:
sensing elements, which are four sensor solar panels, also functioning as power generation panels, placed on a solar panel assembly with wires connected from its backsides to transmit signals;
sockets, for the shade board, which are small circular sockets respectively formed on the solar panel at junction lines between the four specific sensor solar panels;
a cross-divider shade board assembly, made of non-transparent material and formed with downward insertion pins, which is detachably mounted between the four sensor solar panels with pins inserted into the sockets of the solar panel, so that the cross-divider is secured placed between the four sensor panels A, B, C and D, whereby the cross-divider shade board can shade the four sensor panels to generate various intensity of signal by the degree of shades;
signal wires, at the backsides of the four sensor panels connected to the control system for identifying sensor signals; and
a control system, connected with the signal wires from sensor panels' backsides to receive and compare sunlight intensity signals, make judgment, and give commands to the electric push rod and a motor rotary seat for rotation control of the solar panel assembly.

2. The solar tracking system according to claim 1, wherein the control system incorporates a processor for recording voltage, current comparison, and timing parameters, and it can be connected to a monitor/display device via signal wires.

3. The solar tracking system according to claim 1, wherein the solar panel can be made of the material of monocrystalline silicon, polycrystalline silicon, compound semiconductor, or silicon film.

4. The solar tracking system according to claim 1, wherein multiple standard unit solar panels can be assembled to form a solar panel assembly, in which only four are sensor solar panels, together with the cross-divider shade board, are used as the sensing elements to facilitate the turning and rotating of the solar panel assembly so as to automatically track the sunlight. The four sensor solar panels will also function like the standard solar panel to general electricity.
